(19) United States
(12) Patent Application Publication
(10) Pub. No.: US 2009/0071703 A1
(43) Pub. Date: Mar. 19, 2009

(54) CONDUCTIVE PASTE, CIRCUIT BOARD, CIRCUIT ARTICLE AND METHOD FOR MANUFACTURING SUCH CIRCUIT ARTICLE

(75) Inventors: Makoto Imahori, Aichi (JP); Takashi Nakaya, Aichi (JP); Masanori Akita, Shiga (JP); Kousei Nogami, Shiga (JP); Teruo Tagai, Tokyo (JP)

Correspondence Address: OBLON, SPIVAK, MCCLELLAND MAIER & NEUSTADT, P.C., 1940 DUKE STREET, ALEXANDRIA, VA, 22314, US

(73) Assignees: TOAGOSEI CO., LTD., Minato-ku (JP); TORAY ENGINEERING CO., LTD, Chuo-ku (JP); KYORITSU CHEMICAL & CO., LTD., Chiyoda-ku (JP)

(21) Appl. No.: 11/910,981

(22) PCT Filed: Apr. 4, 2006
(86) PCT No.: PCT/JP2006/307133

§ 371 Date: Oct. 9, 2007

(30) Foreign Application Priority Data
Apr. 6, 2005 (JP) 2005-110369

(51) Int. Cl. H05K 1/11; H05K 1/00; B29C 65/00; B29C 65/02

(52) U.S. Cl. 174/261; 252/514; 174/250; 156/182

(57) ABSTRACT

The present invention provides a conductive paste, which is suitable for forming and protecting a circuit, an electrode and the like and is capable of connecting electrodes of a plurality of circuit boards in a short time, a circuit board, a circuit article excellent in moisture and heat resistance and the like, and a method for producing the circuit article. The present conductive paste comprises a conductive material that is scaly, has a mean particle diameter of 1 μm or more and 10 μm or less, and is at least one material selected from the group consisting of Ag, an Ag alloy, an Ag-coated material, and an Ag alloy-coated material, and a resin having a storage modulus at 25° C. of 100 MPa or more. The present circuit board (1′) is provided with a substrate (11) and an electrode (12) formed at least on one side of the substrate (11) using the above conductive paste. On the surface of the electrode (12), an adhesive insulating area composed of a composition having a storage modulus at 25° C. smaller than that of the resin constituting the conductive paste may be provided.

### TECHNICAL FIELD

The present invention relates to a conductive paste, a circuit board, a circuit article and a method for producing the same. More specifically, the present invention relates to a conductive paste that is useful for formation or protection of a circuit, an electrode and the like by coating or printing on a film of polyethylene terephthalate, polycarbonate, polyvinyl chloride, polyimide and the like. Additionally, the present invention also relates to a circuit board in which this conductive paste is used. The present invention further relates to a circuit article in which circuits of the circuit boards above or this circuit board and other circuit board are in electrically connected and to a method for producing the circuit article.

### BACKGROUND ART

Conductive pastes generally contain a binder, a conductive fine powder and the like. There are used a thermosetting epoxy resin, a saturated copolyester resin, a vinyl chloride/vinyl acetate copolymer, a polyurethane resin, an acrylic resin and the like as the binder. And there is used a conductive powder consisting of copper, silver, silver alloys and the like (see, Patent Document 1).

Conductive pastes are used in a wide variety of fields. They are used as a material for circuit patterns on a circuit board, as a constituent material of an electrode for connection (electrical continuity) between electrodes of a plurality of circuit boards, and the like. In the latter case, when electrodes composed of a thermosetting conductive paste are connected, it is usually required to conduct heat treatment at a temperature of 140° C. or more for approximately 30 minutes. In addition, when electrodes composed of a one-part conductive paste containing a thermoplastic resin are connected, heating to 150° C. or higher is necessary.

[Patent Document 1] JP-A H07-41706

### DISCLOSURE OF THE INVENTION

### Problems to be Solved by the Invention

In the case of using electrodes composed of a thermosetting conductive paste, productivity of circuit articles in which plural circuit boards are joined is deteriorated. Additionally, in the case of using electrodes composed of a conductive paste containing a thermoplastic resin, when heat treatments are performed at the high temperatures described above, stress due to elongation or shrinkage of the substrates may concentrate in the connecting parts and lead to a circuit breakdown, depending on the type of substrate.

The objective of the present invention is to provide a conductive paste which is suitable for forming and protecting a circuit, an electrode and the like, is capable of connecting electrodes of a plurality of circuit boards in a short time, and is capable of improving productivity of a circuit article. In addition, the objective of the present invention is to provide a circuit board provided with electrodes formed using this conductive paste. Further, the objective of the present invention is to provide a circuit article which comprises this circuit board and is excellent in environmental resistance such as moisture and heat resistance as well as a method for producing this circuit article.

### Means for Solving Problems

The present inventors conducted thoroughgoing studies to resolve these problems, and pressed a circuit board in which an adhesive insulating area comprising a specific polymer and the like was formed on an electrode that is formed using a conductive paste containing a conductive material having a specific shape and size and a resin having a specific storage modulus and other circuit board having an electrode, so that the electrodes were facing each other. As a result, the inventors found that components constituting the adhesive insulating area moved to a circumference of the electrodes, the circuit boards were joined, and good electrical conductivity between electrodes was obtained with this configuration to complete the present invention.

The present invention is as follows. It is noted that “adhesive” involves adhesion.

[1] A conductive paste characterized in comprising a conductive material that is scaly, has a mean particle diameter of 1 μm or more and 10 μm or less, and is at least one material selected from the group consisting of Ag, an Ag alloy, an Ag-coated material, and an Ag alloy-coated material, and a resin that has a storage modulus at 25° C. of 100 MPa or more.
[2] The conductive paste according to [1] above, wherein the resin is a polyester resin.
[3] A circuit board characterized in comprising a substrate and an electrode which is formed at least on one surface of the substrate using the conductive paste according to [1] above.
[4] The circuit board according to [3] above, wherein the circuit board is used for forming an adhesive insulating area, which comprises a composition having a storage modulus that is smaller than the storage modulus at 25° C. of the resin contained in the conductive paste, on a surface of the electrode.
[5] The circuit board according to [3], wherein a ten point height of roughness profile of a surface of the electrode is 15 μm or more.
[6] The circuit board according to [3], wherein the circuit board further comprises an adhesive insulating area on a surface of the electrode, and wherein a storage modulus at 25° C. of a composition that constitutes the adhesive insulating area is smaller than a storage modulus at 25° C. of the resin that is contained in the conductive paste.
[7] The circuit board according to [6] above, wherein the adhesive insulating area comprises at least one polymer selected from the group consisting of a styrene-isoprene-styrene block copolymer, a styrene-butadiene-styrene block copolymer and hydrogenated polymers of these polymers, a tackifier resin, and an oil and/or a liquid hydrocarbon-based plasticizer.
[8] The circuit board according to [7] above, wherein content of the polymer is in the range from 10 to 60 parts by mass based on 100 parts by mass of total of the polymer and the tackifier resin.
[9] The circuit board according to [7] above, wherein total content of the oil and/or the liquid hydrocarbon-based plasticizer is in the range from 5 to 30 parts by mass based on 100 parts by mass of total of the polymer and the tackifier resin.
[10] A circuit article characterized in comprising the circuit board according to [3] above.
[11] A circuit article which comprises a plurality of the circuit boards according to [6] above, and wherein one circuit board and other circuit boards among the circuit boards are joined with an adhesive insulating composition that constitutes the adhesive insulating area of the one circuit board, characterized in that the one circuit board and the other circuit boards are in electrically connected due to contact between an electrode of the one circuit board and an electrode of the other circuit boards.
[12] A circuit article which comprises the circuit board according to [6] above and other circuit board provided with an electrode on its surface, wherein the circuit board and the other circuit board are joined with an adhesive insulating composition that constitutes an adhesive insulating area of the circuit board, characterized in that circuits of both circuit boards are in electrically connected due to contact between an electrode of the circuit board and an electrode of the other circuit board.
[13] A method for manufacturing a circuit article, characterized in comprising: selecting two circuit boards out of a plurality of said circuit boards according to [6] above, facing an electrode of the one circuit board to an electrode of the other circuit board; and attaching the two circuit boards by using adhesive insulating compositions that constitute adhesive insulating area on the each circuit board, while getting electric contact between the two electrodes.
[14] The method for manufacturing a circuit article according to [13] above, wherein the attaching process involves applying pressure while heating.
[15] A method for manufacturing a circuit article, characterized in comprising: providing a circuit board which has an electrode on its surface and the circuit board according to [6] above, facing an electrode of the circuit board to an electrode of the other circuit board; and attaching the two circuit boards by using adhesive insulating compositions that constitute adhesive insulating area on the each circuit board, while getting electric contact between the two electrodes.
[16] The method for manufacturing a circuit article according to [15] above, wherein the attaching process involves applying pressure while heating.

### EFFECT OF THE INVENTION

The conductive paste of the present invention is suitable for formation, protection and the like of a circuit, an electrode and the like by coating or printing it on a film of polyethylene terephthalate, polycarbonate, polyvinylchloride, polyimide and the like. In addition, the conductive paste of the present invention leads to a connection between electrodes of plural circuit boards in a short time and an improvement in producing a circuit article.

The circuit board of the present invention comprises a substrate and an electrode which is formed at least on one surface of the substrate using the conductive paste described in above 1 or 2. According to the circuit board of the present invention, the adhesive insulating area comprising a composition having a storage modulus that is smaller than the storage modulus at 25° C. of the resin that contained in the conductive paste, can be suitably formed on the surface of the above electrode.

In the case where an adhesive insulating area formed on a surface of the above-mentioned electrode and the storage modulus at 25° C. of the composition constituting the adhesive insulating area is smaller than the storage modulus at 25° C. of the resin contained in the above-mentioned conductive paste, connections between the electrode of the present circuit board and other circuit board having an electrode can be performed in a short time. In the case where a ten point height of roughness profile of a surface of the electrode is 15 μm or more, when the present circuit board is subjected to joining with other circuit board by pressing or the like, the adhesive insulating area can be broken and the electrodes of the circuit boards can be efficiently brought into contact to an electrical continuity.

Further, in the case where the adhesive insulating area contains a specific polymer and a tackifier resin in specific amounts, a connection between the electrodes can be performed at a low temperature range of approximately 20° C. to 80° C. The productivity of a circuit article can therefore be improved.

Moreover, in the case where other electrodes (circuit portions) other than the electrodes to be connected are not facing during the joining of a plurality of circuit boards, these portions need not be masked. The circuit board may therefore be one provided with the adhesive insulating area over the entire surface of the substrate in this case. As a result, processing is simplified, and a strongly bonded circuit article can be obtained.

The circuit article of the present invention is excellent in electrically connected between plural circuit boards and in particular between electrodes. In the case where the adhesive insulating area contains at least one polymer selected from the group consisting of a styrene-isoprene-styrene block copolymer, a styrene-butadiene-styrene block copolymer and hydrogenated polymers of these polymers, a tackifier resin, and an oil and/or a liquid hydrocarbon-based plasticizer, environmental resistance such as moisture and heat resistance is also excellent.

According to the method for manufacturing a circuit article of the present invention, when the circuit board of the present invention and other circuit board having an electrode are pressed so that the electrodes face one another, the adhesive insulating area at the contacting parts of the electrodes deforms and fills a space around the electrodes. Thereby, a circuit article in which the circuit boards are joined and the electrodes have a favorable electrical continuity can be obtained.

In the case where the adhesive insulating area is a pressure-sensitive adhesive layer comprising a specific polymer, a tackifier resin and the like, plural circuit boards can be readily joined by merely pressing without heating. Furthermore, in the case where the above-mentioned adhesive insulating area is a hot-melt type adhesive layer, heating and pressing are combined on the basis of a softening temperature of the polymer or the tackifier resin to readily join plural circuit boards.

Therefore, the method for manufacturing a circuit article of the present invention is a highly productive method for connecting circuits, available for a lighter, more compact and low-cost design electronic component such as RFID tags (including non-contact ID tags and non-contact ID cards).

### BRIEF DESCRIPTION OF THE DRAWINGS

FIG. 1 is a schematic cross-sectional view showing an example of a circuit board (I) of the present invention.

FIG. 2 is a schematic plan view showing an example of a circuit board (II) of the present invention.

FIG. 3 is a cross-sectional view of the line X-X of the circuit board (II) of FIG. 2.

FIG. 4 is a schematic cross-sectional view showing another example of the circuit board (II) of the present invention.

FIG. 5 is a schematic cross-sectional view showing another example of the circuit board (II) of the present invention.

FIG. 6 is a schematic cross-sectional view showing another example of the circuit board (II) of the present invention.

FIG. 7 is a schematic cross-sectional view showing another example of the circuit board (II) of the present invention.

FIG. 8 is a schematic cross-sectional view showing another example of the circuit board (II) of the present invention.

FIG. 9 is a schematic cross-sectional view showing an example of a circuit article (K1) of the present invention and of the method for producing the same.

FIG. 10 is a schematic cross-sectional view showing an example of a circuit article (K2) of the present invention and of the method for producing the same.

FIG. 11 is a schematic cross-sectional view showing another example of a circuit article (K2) of the present invention and of the method for producing the same.

FIG. 12 is a schematic cross-sectional view showing another example of the circuit article of the present invention;

FIG. 13 is a schematic plan view showing an electrode formed in Example 5.

FIG. 14 is a schematic plan view showing a circuit board produced in Example 5 and showing the adhesive insulating area formed on the surface of the electrode of FIG. 13 (L).

FIG. 15 is a schematic plan view showing the circuit article produced and evaluated in Example 5.

### DESCRIPTION OF REFERENCE NUMERALS AND SIGNS

1, 1a, 1b and 1″; circuit board (II),
1c; other circuit board (II),
1′; circuit board (I),
11, 11a, 11b, 11c and 11c′; substrate,
12, 12a, 12a′, 12b, 12c and 12c′; electrode,
13, 13a, 13b, 131 and 132; adhesive insulating area,
133; other adhesive insulating area,
135a, 135b, 135c and 135d; joining part,
2, 2′ and 2″; circuit article,
31 and 32; resistance measuring position.

### BEST MODE FOR CARRYING OUT THE INVENTION

### 1. Conductive Paste

The conductive paste of the present invention is characterized in comprising a conductive material that is scaly, has a mean particle diameter of 1 μm or more and 10 μm or less, and is at least one material selected from the group consisting of Ag, an Ag alloy, an Ag-coated material, and an Ag alloy-coated material, and a resin that has a storage modulus at 25° C. of 100 MPa or more. The conductive paste of the present invention is coated, printed, or otherwise applied to the surface of a substrate of a film, paper, woven cloth, non-woven cloth, plate or a combination thereof. The conductive paste of the present invention also includes a solvent, an additive and the like as necessary.

The conductive material according to the present invention (hereinafter referred to as “conductive material [A]”) is at least one material selected from Ag (silver), an Ag alloy, an Ag-coated material, and an Ag alloy-coated material. Two or more types thereof may be used in combination as the conductive material [A]. Examples of the Ag alloy include Ag—Pd alloys, Ag—Ni alloys, Au—Ag alloys, Ag—Cu alloys and the like. In the case where the above-mentioned conductive material [A] is an Ag-coated material and an Ag alloy-coated material, examples of a constituent material of the core part constituting a coated material include a resin such as poly methyl methacrylate and polystyrene. The shape of the core part is usually scaly.

The shape of the above-mentioned conductive material [A] is substantially flat and finely scaly. The aspect ratio is preferably 6 or more and further preferably 8 or more. When the aspect ratio is too small, it may be difficult to obtain contact between the conductive materials, particularly in the lateral direction, and the resistance tends to be higher.

In addition, the mean particle diameter of the abovementioned conductive material [A] is in the range from 1 to 10 μm and preferably from 1.5 to 8 μm. When the mean particle diameter is in this range, the conductive paste of the present invention is excellent in printability. Further, when the mean particle diameter is in this range, the ten point height of roughness profile (according to JIS B0601-2001) for the surface of a film formed using the conductive paste can be 15 μm or more. The above-mentioned mean particle diameter can be measured using a laser diffracting or scattering apparatus for measuring particle size distributions, and the like.

The conductive paste of the present invention may comprise other conductive material (hereinafter referred to as “conductive material [A′]”). This conductive material [A′] is not particularly limited so long as Ag and an Ag alloy are not contained. Examples of the conductive material [A′] include a metal such as Co, Ni, Cr, Cu, W, Al and In; an alloy of these metals such as Au—Pd alloys, Au—Pt alloys, Pt—Pd alloys, Cu—Sn alloys and Cu—Zn alloys; carbon such as graphite, and carbon; and the like. The conductive material [A′] may also contain a coated material where a core member is covered with the above-mentioned materials. These materials may be used alone or in combination of two or more types thereof.

The shape and size of the above-mentioned conductive material [A′] are not particularly limited. The shape of the above-mentioned conductive material [A′] may be spherical, polyhedral, linear (dendritic), chestnut-like, scaly, or the like. The mean particle diameter of the above-mentioned conductive material [A′] is preferably 1 μm or more and 10 μm or less.

In the case of combining the conductive material [A] and the conductive material [A′], the amount of the conductive material [A′] to be used is preferably 400 parts by mass or less, and more preferably more than 0 part by mass and less than or equal to 100 parts by mass relative to 100 parts by mass of the conductive material [A].

In the conductive paste of the present invention, the total content of conductive material is preferably in the range from 85 to 93 parts by mass and more preferably from 87 to 90 parts by mass based on 100 parts by mass of the total amount of solids in the conductive paste. This ratio is satisfied in both a case where the conductive material [A] is contained singly as the conductive material and a case where the conductive material [A] and the conductive material [A′] are used in combination for the conductive paste of the present invention. If the content of the conductive material is too small, a high electrical conductivity may not be obtained. On the other hand, if the content is too large, the adhesion by the conductive paste may be deteriorated and peeling may occur.

The content ratio of the above-mentioned conductive material in the conductive paste of the present invention is preferably in the range from 50% to 85% by mass, more preferably from 52% to 80% by mass and further preferably from 55% to 75% by mass relative to the entire paste. If the content ratio is too small, contact between the conductive materials may be decreased and conductivity may be reduced. On the other hand, if the content ratio is too large, the viscosity of the conductive paste may be increased and a conductive pattern may not be formed with high precision using the conductive paste. As a result, the strength of the conductive pattern may be decreased and conductivity may be reduced.

The resin according to the present invention (hereinafter referred to as “resin [B]”) may be a thermoplastic resin, a thermosetting resin, light-curing resin (UV-curing resin or the like), or other resin so long as the storage modulus at 25° C. is 100 MPa or more, preferably in the range from 100 to 1,000 MPa. The storage modulus according to the present invention is a value measured when the resin [B] is a solid. Therefore, when the above-mentioned resin [B] is a thermoplastic resin, the above-mentioned storage modulus is the value measured for a solid obtained by a method for fabricating a test piece that can be used in measuring solid-state characteristics (e.g., by a method involving using heat to appropriately adjust the viscosity, and then cooling). When the above-mentioned resin [B] is a thermosetting resin (composition) or a light-curing resin (composition), the above-mentioned storage modulus is the value measured for the cured compound obtained by heating or light irradiation. If an electrode is formed using a conductive paste containing a resin having a storage modulus of less than 100 MPa, when an adhesive insulating area is formed on an electrode and circuit board is made, the constituent materials of the adhesive insulating area will remain behind when the circuit board is pressure bonded together with other circuit board so that the electrodes face one another, and good electrical conductivity may not be obtained.

The above-mentioned resin [B] may be used according to the properties and example thereof includes a thermoplastic polyester resin, an epoxy resin, a polyurethane resin, a phenol resin, an unsaturated polyester resin, a vinyl chloride-vinyl acetate copolymer, a (meth)acrylic resin, a polybutadiene resin, a polyvinylacetate-based resin, a polyimide-based resin and the like. These may be used singly or in combinations of two or more types thereof. Among these, a thermoplastic polyester resin, an epoxy resin and a polyurethane resin are preferable from the standpoint of adhesivity to the substrate used in a circuit board, compatibility with a conductive material, and other concerns. And a thermoplastic polyester resin is particularly preferred. The above-mentioned resin [B] may also comprise a resin having a storage modulus at 25° C. less than 100 MPa so long as the overall storage modulus at 25° C. is 100 MPa or more.

The content ratio of the above-mentioned resin [B] in the conductive paste of the present invention is preferably in the range from 6.5% to 15% by mass, more preferably from 9.5% to 13% by mass and further preferably from 10% to 13% by mass based on 100% by mass of the total of the conductive material and the resin [B]. Additionally, the content ratio of the above-mentioned resin [B] in the conductive paste of the present invention is preferably in the range from 10% to 20% by mass and more preferably from 10% to 15% by mass relative to the entire paste. If the content ratio is too small, printability and adhesivity to the substrate may not be sufficient. On the other hand, if the content ratio is too large, conductivity of an electrode to be formed may not be sufficient.

The conductive paste of the present invention may comprise a solvent and an additive other than the conductive material [A] and the resin [B] mentioned above. Examples of the solvent include an ester-based solvent, a ketone-based solvent, an etherester-based solvent, a chlorine-based solvent, an alcohol-based solvent, an ether-based solvent and a hydrocarbon-based solvent and the like. These may be used alone or in combination of two or more types thereof. Among these solvents, an ester-based solvent, a ketone-based solvent and an etherester-based solvent are preferred.

Example of the ester-based solvent includes methyl acetate, ethyl acetate, isopropyl acetate, isobutyl acetate, butyl acetate, amyl acetate and the like.

Example of the ketone-based solvent includes methyl ethyl ketone, methyl isobutyl ketone, methyl isoamyl ketone, methyl amyl ketone, ethyl amyl ketone, isobutyl ketone, methoxymethyl pentanone, cyclohexanone, diacetone alcohol, isophorone and the like.

Example of the etherester-based solvent includes 2-methoxyethyl acetate (methyl cellosolve acetate), 2-ethoxyethyl acetate (ethyl cellosolve acetate), 2-butoxyethyl acetate (butyl cellosolve acetate), 3-methoxybutyl acetate, diethyleneglycol monomethylether acetate (methyl carbitol acetate), diethyleneglycol monoethylether acetate (ethyl carbitol acetate), diethyleneglycol mono n-butylether acetate (buthl carbitol acetate) and the like.

The content ratio of the above-mentioned solvent in the conductive paste of the present invention is preferably in the range from 10 to 70 parts by mass, more preferably from 15 to 60 parts by mass and further preferably from 20 to 50 parts by mass based on 100 parts by mass of total of the conductive material and the resin. Additionally, the content ratio of the above-mentioned solvent in the conductive paste of the present invention is preferably in the range from 10% to 50% by mass and more preferably from 25% to 45% by mass based on the entire paste. If the content ratio is too small, the viscosity may be too high and the conductive pattern may not be coated uniformly. On the other hand, if the content ratio is too large, printability of the conductive paste and adhesivity to the substrate may not be sufficient.

Examples of the additive include a corrosion inhibitor, a coupling agent, a hardener, a leveling agent, an antifoaming agent, a dispersion stabilizing agent, a thixotropic agent and the like.

Examples of the corrosion inhibitor include a benzothiazole a benzimidazole and the like. In the case of using the corrosion inhibitor, the amount to be used is usually in the range from 0.1 to 3 parts by mass relative to 100 parts by mass of the resin [B].

The coupling agent and the hardener are selected according to the type of resin [B]. Examples of the coupling agent include a titanium-based coupling agent such as titanium di(dioctyl pyrophosphate) oxyacetate and di(dioctyl pyrophosphate) ethylene titanate; a silane-based coupling agent such as γ-(2-aminoethyl) aminopropyl trimethoxysilane and γ-glycidoxypropyl trimethoxysilane; and the like.

The conductive paste of the present invention is suitable for forming an electrode which constitutes the circuit board of the present invention described later.

### 2. Circuit Board

The circuit board of the present invention (hereinafter referred to as “circuit board (I)”) is characterized in comprising a substrate and an electrode which is formed at least on one surface of the substrate using the above-mentioned conductive paste. The circuit board (I) of the present invention can be used for forming an adhesive insulating area which comprises a composition (hereinafter referred to as “adhesive insulating composition”) having a storage modulus that is smaller than the storage modulus at 25° C. of the resin contained in the above-mentioned conductive paste, on a surface of the above-mentioned electrode.

The above-mentioned substrate may be a substrate of a film, paper, woven cloth, non-woven cloth, mat, plate or a combination of two or more types thereof. Examples of the principal constituent material of the above-mentioned substrate include a polyester-based resin such as polyethylene terephthalate, a polycarbonate resin such as an aromatic polycarbonate, a polyolefin-based resin, a polyamide-based resin, a polyimide-based resin, an ethylene-vinyl alcohol copolymer, a poly vinyl alcohol-based resin, a poly vinylchloride-based resin, a poly vinylidene chloride-based resin, a polystyrene-based resin, an acrylonitrile-butadiene-styrene-based resin, a polyethersulfone-based resin, a cellulose and the like. In addition, when the woven cloth or the non-woven cloth is used as the above-mentioned substrate, a fiber constituting the woven cloth or the non-woven cloth mentioned above may be an inorganic fiber or an organic fiber including a glass fiber, an alumina fiber, a polyester fiber and a polyamide fiber. Among these, a polyester-based resin, a polyamide-based resin and a poly vinylchloride-based resin are preferred.

The above-mentioned substrate may be one whose surface is be primarily treated by corona-discharge treatment, plasma treatment, ultraviolet rays treatment, electron rays treatment, flame-plasma treatment, ozone treatment or the like in order to improve the adhesion of the conductive paste, and the like.

The above-mentioned electrode is one formed using the above-mentioned conductive paste. For example, the above-mentioned electrode is one obtained by coating or printing to a coated layer having a prescribed pattern and drying to form a film. The surface of this electrode preferably has a ten point height of roughness profile of 15 μm or more, and more preferably 20 μm of more, where the roughness is measured in accordance with JIS B0601-2001. It is noted the upper limit is usually 50 μm. In the case where the above-mentioned ten point height of roughness profile is too small, when the adhesive insulating area is formed using the above-mentioned adhesive insulating composition, and another circuit board of the present invention (hereinafter referred to as “circuit board (II)”) is produced, the circuit board (I) and the circuit board (II), or, alternatively, the circuit boards (II) are pressed so that the electrodes are facing, the adhesive insulating area may not be broken and a favorable electrical continuity may not be obtained.

The surface of the above-mentioned electrode may be flat or uneven. In addition, the thickness (average thickness) of the above-mentioned electrode is usually in the range from 10 to 150 μm, and preferably from 15 to 100 μm. If the thickness is too thin, the resistance may be increased. And if the electrode is too thick, printing on the surface may be affected in applications for cards, tags and the like.

The above-mentioned electrode is formed at least on one surface of the substrate. An interlayer may also be formed between the electrode and the substrate. Further, the above-mentioned substrate has two or more electrodes may on the same surface thereof. The above-mentioned electrode may also be formed on all faces of the substrate.

The circuit board (I) of the present invention will be described using some drawings.

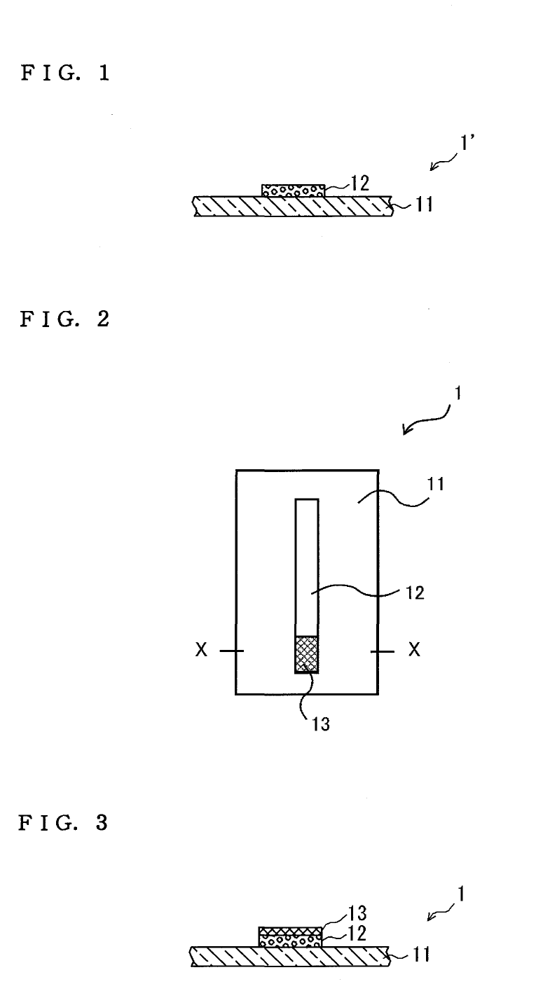

FIG. 1 is a schematic cross-sectional view that shows an example of the circuit board (I). A circuit board 1′ is provided with a substrate 11 and an electrode 12 which is disposed on the surface of the substrate 11.

The other circuit board (II) of the present invention is provided with an adhesive insulating area on a surface of the above-mentioned electrode. The adhesive insulating area of the other circuit board (II) of the present invention is formed using the above-mentioned adhesive insulating composition. The constituent material of this adhesive insulating area is not particularly limited so long as the adhesive insulating area is an insulator at the usage temperature of the circuit board (II) and the circuit article obtained by using the circuit board, and particularly at near room temperatures of 20° C. to 30° C. (hereinafter referred to as “ordinary temperature”). The adhesiveness of this adhesive insulating area may be still led at ordinary temperature, or may be led due to pressure, heat, or light irradiation.

The above-mentioned adhesive insulating area (adhesive insulating composition) comprises preferably a polymer such as a diene-based polymer, a polyurethane and a polyester, a tackifier resin, and an oil and/or a liquid hydrocarbon-based plasticizer (hereinafter referred to collectively as “liquid material”).

The above-mentioned polymer is preferably a diene-based polymer. Examples of the diene-based polymer include a styrene-isoprene-styrene block copolymer and a styrene-butadiene-styrene block copolymer, hydrogenated polymers thereof and the like. These may be used alone or in combination of two or more types thereof. In addition, this diene-based polymer may be used in combination with other polymer.

The styrene-isoprene-styrene block copolymer may be used commercially-supplied products such as “SIS-based block copolymer” and “SIS-based (thermoplastic) elastomer”. The commercially-supplied products include “KRATON D-1107CP”, “KRATON D-1112” and “KRATON D-1117” (trade name) manufactured by Shell Chemical Ltd., and the like.

The styrene-butadiene-styrene block copolymer may be used commercially-supplied products such as “SBS-based block copolymer” and “SBS-based (thermoplastic) elastomer”. The commercially-supplied products include a linear type block polymer such as “KRATON D-1101” and “KRATON D-1118” (trade name) manufactured by Shell Chemical Ltd., a branched type block polymer such as “KRATON D-1184” and “KRATON D-1122X” (trade name) by same company, and the like.

Additionally, the hydrogenated polymer thereof is generally called “SEBS-based (thermoplastic) elastomer”. These hydrogenated polymers may be used commercially-supplied products. Examples thereof include “KRATON G-1650”, “KRATON G-1652” and “KRATON G-1657” (trade name) manufactured by Shell Chemical Ltd., “SEPTON 2002”, “SEPTON 2043” and “SEPTON 2007” (trade name) manufactured by KURARAY CO., LTD., and the like. Hydrogenation degree of these hydrogenated polymers is not particularly limited and is usually in the range from 90% to 100%.

The preferable polystyrene-converted weight-average molecular weights of the blocks in the above-mentioned block copolymers according to gel permeation chromatography (GPC) are in the range from 2,000 to 125,000 for the styrene blocks and in the range from 10,000 to 250,000 for the butadiene or isoprene blocks. The overall proportion of styrene blocks in the polymer is preferably in the range from 10% to 50% by mass relative to the entire polymer.

Among these polymers, a styrene-isoprene-styrene block copolymer and a hydrogenated polymer thereof are particularly preferable. These polymers lead to an excellent adhesiveness for the circuit board (I) and the circuit board (II), or, alternatively, for the circuit boards (II). Additionally, when these polymers are used in combination, a circuit article provided also with heat resistance can be obtained. The ratio of the styrene-isoprene-styrene block copolymer and the hydrogenated polymer thereof in combination is preferably 30% to 80% by mass and 20% to 70% by mass, respectively, based on 100% by mass of the total of these polymers.

The content ratio of the above-mentioned polymer constituting the adhesive insulating area is preferably in the range from 5% to 70% by mass, more preferably from 10% to 60% by mass, and further preferably from 20% to 50% by mass relative to the entire adhesive insulating area.

Examples of the above-mentioned tackifier resin include a petroleum-based resin, a rosin-based resin, a terpene-based resin and the like. These may be used alone or in combination of two or more types thereof.

Examples of the above-mentioned petroleum-based resin include an aliphatic-based petroleum resin, an aromatic-based petroleum resin, a copolymer-based petroleum resin, a hydrogenated petroleum resin and the like. Among these resins, the hydrogenated petroleum resin is preferable. This petroleum-based resin may be used commercially-supplied products. Examples thereof include “ARKON P” and “ARKON M” (trade name) manufactured by ARAKAWA CHEMICAL INDUSTRIES LTD., “Escorez” (trade name) manufactured by TonenGeneral Sekiyu K. K., “Hi-rez” (trade name) manufactured by Mitsui Chemicals, Inc., “Quintone” (trade name) manufactured by ZEON CORPORATION, “WINGTACK” (trade name) manufactured by Goodyear Tire and Rubber Company, “STA-TAC” (trade name) manufactured by DAINIPPON INK and CHEMICALS, Inc., “TOHO PETOROSIN” (trade name) manufactured by TonenGeneral Sekiyu K. K., “TACKACE” (trade name) manufactured by Mitsui Chemicals, Inc., “FTR” (trade name) manufactured by Mitsui Chemicals, Inc. and the like.

Examples of the above-mentioned rosin-based resin include a natural rosin, a polymerized rosin and the like. The rosin-based resin also includes derivatives of the rosins. Examples thereof include an esterified rosin such as a pentaerythrite ester rosin and a glycerin ester rosin, a hydrogenated rosin thereof, and the like. This rosin-based resin may be used commercially-supplied products. Examples thereof include “GUM ROSIN”, “WOOD ROSIN”, “ESTER GUM A”, “ESTER GUM H”, “PENSEL A” and “PENSEL C” (trade name) manufactured by ARAKAWA CHEMICAL INDUSTRIES LTD., “PENTALYN A”, “FORAL AX”, “FORAL 85”, “FORAL 105” and “PENTALYN C” (trade name) manufactured by Rika Hercules Co., Ltd., and the like.

Further, examples of the above-mentioned terpene-based resin include a polyterpene-based resin, a terpene phenol-based resin and the like. A hydrogenated resin thereof may also be used. This terpene-based resin may be used commercially-supplied products. Examples thereof include “PICOLIGHT S” and “PICOLIGHT A” (trade name) manufactured by Rika Hercules Co., Ltd., “YS RESIN”, “YS POLYSTER T” and “CLEARON” (trade name) manufactured by YASUHARA CHEMICAL CO., LTD. and the like.

The content ratio of the above-mentioned tackifier resin constituting the adhesive insulating area is preferably in the range from 20% to 80% by mass, more preferably from 30% to 70% by mass, and further preferably from 40% to 60% by mass relative to the entire adhesive insulating area.

The content ratio of the polymer and the tackifier resin that constitute the above-mentioned adhesive insulating area is preferably 10% to 60% by mass and 40% to 90% by mass, respectively, and more preferably 30% to 60% by mass and 40% to 70% by mass, respectively, based on 100% by mass of the total of these polymers. This range leads to a sufficient adhesiveness.

The above-mentioned liquid material is an oil and/or a liquid hydrocarbon-based plasticizer. The kinematic viscosity at 40° C. of this liquid material is preferably in the range from 1 to 10,000 mm²/s. In the case where the above-mentioned kinematic viscosity is in this range, when the circuit board (I) and the circuit board (II), or, alternatively, the circuit boards (II) are joined, the above-mentioned liquid material will readily move from a surface of the electrode to a circumference along with the above-mentioned polymer and the above-mentioned tackifier resin.

The above-mentioned oil is preferably an oil for processing (process oil) and an oil for increasing the volume that are used for synthetic rubbers, and the like. Examples of the oil include paraffin-based, naphthene-based, and aromatic hydrocarbon-based mineral oils, high-boiling fractions of these oils, a liquid resin such as a liquid rosin and liquid terpenes, and the like. These may be used alone or in combination of two or more types thereof. This oil may be used commercially-supplied products. Examples of the process oil include “DIANA PROCESS OIL” (trade name) manufactured by Idemitsu Kosan Co., Ltd., “SHELLFLEX” (trade name) manufactured by Shell Chemical Ltd., “Dimerone”, “YS oil” and “Rubbersoft” (trade name) manufactured by YASUHARA CHEMICAL CO., LTD. and the like.

In addition, examples of the above-mentioned liquid hydrocarbon-based plasticizer include a liquid hydrocarbon-based synthetic rubber such as polybutene, polyisobutylene, polyisoprene, polybutadiene and hydrogenated polymer thereof, and the like. These may be used alone or in combination of two or more types thereof. This liquid hydrocarbon-based plasticizer may be used commercially-supplied products. Examples thereof include “KURAPRENE LIR” and “Hydrogenated. LIR” (trade name) manufactured by KURARAY CO., LTD., “Idemitsu Polybutene” (trade name) manufactured by Idemitsu Kosan Co., Ltd., and the like.

The above-mentioned liquid material may be used the above-mentioned oil singly, or the above-mentioned liquid hydrocarbon-based plasticizer singly. Further, the above-mentioned oil and the above-mentioned liquid hydrocarbon-based plasticizer may also be used in combination as the above-mentioned liquid material.

The content ratio of the above-mentioned liquid material constituting the above-mentioned adhesive insulating area is preferably in the range from 20% to 80% by mass, more preferably from 30% to 70% by mass, and further preferably from 40% to 60% by mass relative to the entire adhesive insulating area.

In addition, the content ratio of the above-mentioned liquid material is preferably in the range from 5 to 30 parts by mass and more preferably from 15 to 30 parts by mass based on 100 parts by mass of the total of the above-mentioned polymer and the above-mentioned tackifier resin. If the content ratio of the above-mentioned liquid material exceeds 30 parts by mass, the cohesive force between the above-mentioned polymer and the above-mentioned tackifier resin may be lowered to reduce adhesiveness. On the other hand, if the content ratio of the above-mentioned liquid material is less than 5 parts by mass, the adhesiveness at lower temperatures of approximately 20° C. to 60° C. may be reduced.

The above-mentioned adhesive insulating area (adhesive insulating composition) may comprise an additive such as a flame retardant, an antifoaming agent, a coupling agent, an antioxidant, an antiaging agent, a heat stabilizer, a colorant and an inorganic filler. Examples of the flame retardant include a bromide compound, a phosphorous-containing compound and the like. Examples of the antifoaming agent include a silicone-based compound and the like. Examples of the colorant include carbon black, an organic pigment and the like. Examples of the inorganic filler include calcium carbonate, talc and the like. The above-mentioned other additive may be used alone or in combination of two or more types thereof.

The storage modulus at 25° C. of the above-mentioned adhesive insulating composition is smaller than the storage modulus at 25° C. of a resin constituting the above-mentioned conductive paste. This property leads to a favorable electrical continuity between the electrodes during pressing and the like. The above-mentioned storage modulus at 25° C. of the adhesive insulating composition is preferably 20% or less, more preferably 10% or less and further preferably from 0.01% to 5% based on the above-mentioned storage modulus at 25° C. of the resin constituting the conductive paste. In addition, the above-mentioned storage modulus of the adhesive insulating composition is preferably in the range from 10 kPa to 10 MPa, and more preferably from 20 kPa to 5 MPa. If the storage modulus is too large, the above-mentioned adhesive insulating composition may not spread during pressing or the like. On the other hand, if the storage modulus is too small, the cohesion may be lowered and sufficient adhesiveness may not be exhibited.

The thickness of the above-mentioned adhesive insulating area is preferably in the range from 10 to 400 μm and more preferably from 15 to 200 μm.

The circuit board (II) of the present invention will be described using some drawings.

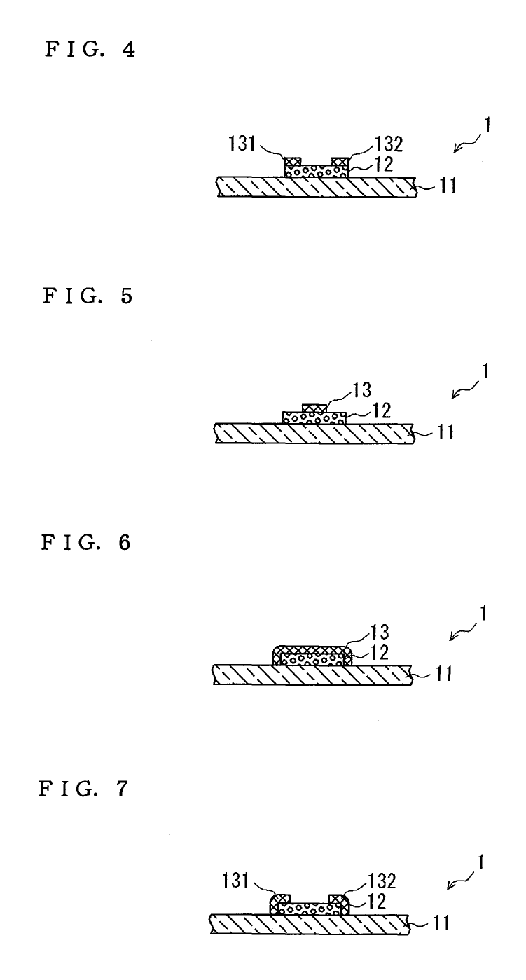

The circuit board 1 in FIG. 2 is a schematic plan view that shows an example of the circuit board (II). The circuit board 1 is provided with a substrate 11, an electrode 12 which is disposed on the surface of the substrate 11, and an adhesive insulating area 13 which is disposed on a part of the surface of this electrode 12. FIG. 3 is a cross-sectional view cut along the line X-X in FIG. 2 and shows the adhesive insulating area 13 formed on the surface of the electrode 12 with the same width as the electrode 12.

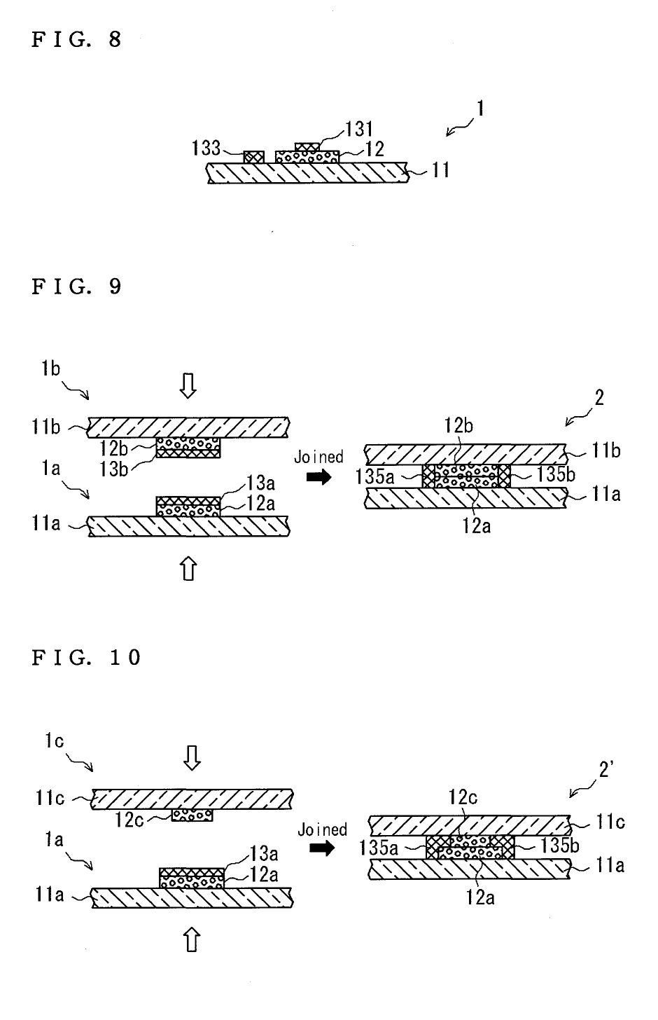

FIGS. 4 to 8 are schematic cross-sectional views that show circuit boards (II) of the present invention as described above. FIGS. 4 to 8 are drawings in which the area near the center of the portion on which the electrode 12 and the adhesive insulating area 13 (131, 132) are formed is cut perpendicularly. FIG. 4 is an embodiment provided with adhesive insulating areas 131 and 132 on both ends of the surface of the electrode 12. FIG. 5 is an embodiment provided with the adhesive insulating area 13 on the central part of the surface of the electrode 12. FIG. 6 is an embodiment provided with the adhesive insulating area 13 covering the entire surface of the electrode 12. FIG. 7 is an embodiment provided with the adhesive insulating areas 131 and 132 covering both ends as well as the edge parts of the surface of the electrode 12. FIG. 8 is an embodiment provided with other adhesive insulating area 133 on the surface of the substrate 11 in addition to the embodiment in FIG. 5. This adhesive insulating area 133 may have the same composition as the adhesive insulating area 13.

The electrode 12 and the adhesive insulating area 13 may also be positioned on the opposite face of the circuit boards (II) shown in FIGS. 3 to 8, as described above.

The circuit board (II) of the present invention may be produced by a method provided with a step wherein the conductive paste is coated or printed on a substrate to form an electrode (hereinafter referred to as “step (1)”), and a step wherein the adhesive insulating composition is used to form an adhesive insulating area on the surface of the electrode (hereinafter referred to as “step (2)”).

The method for forming the electrode on the substrate in the step (1) is not particularly limited. The above-mentioned electrode is usually formed by coating or printing to a coated layer having a prescribed pattern and drying to form a film. When the coated layer is formed by printing, screen printing, ink-jet printing and the like may be applied. In addition, drying may be natural drying at ordinary temperature, drying accompanied by heating (hot-air drying, vacuum drying or the like), and the like. The conditions and other factors involved in the method of drying are selected in consideration of the components contained in the conductive paste to be used, particularly in consideration of types and characteristics of a resin, a solvent and the like.

In the step (2), the adhesive insulating area is formed on a surface of the above-mentioned electrode using the adhesive insulating composition.

The above-mentioned adhesive insulating composition is preferably used one having at least one property among ordinary temperature type, pressure-sensitive type, heat-sensitive type and photosensitive type since the constituent components of this adhesive insulating area have characteristics as described above. In the present invention, a pressure-sensitive type composition and a pressure-sensitive and heat-sensitive type composition (hot-melt composition) are particularly preferred.

The above-mentioned adhesive insulating composition has a melt viscosity at 190° C. of preferably 100,000 mPa or less in consideration of printability on a surface of the electrode surface, and the like. More preferable is from 1,000 to 20,000 mPa. If the melt viscosity is too high, the adhesive insulating composition may generate stringiness and lead to an inferior workability. On the other hand, if the melt viscosity is too low, the adhesive insulating composition may spread beyond the printing locations and lead to defects in electrical conduction, external appearance and the like.

Additionally, the storage modulus at 25° C. of the above-mentioned adhesive insulating composition is preferably in the range from 10 kPa to 10 MPa, and more preferably from 20 kPa to 5 MPa. If this storage modulus is too large, it may be difficult to spread the above-mentioned adhesive insulating composition during pressing. On the other hand, if the storage modulus is too small, the cohesion may be lowered and sufficient adhesiveness may not be exhibited.

The method for forming the above-mentioned adhesive insulating area is not particularly limited. The above-mentioned adhesive insulating area can be obtained by forming a coated layer with usually a coating method such as brush coating and roll coating; a printing method such as screen printing, and the like, and then still standing or heating to form a film. Further, other examples include a method in which a coated layer having a prescribed shape is formed on a release material made of a polyolefin such as polypropylene, a polyester such as polyethylene terephthalate and a fluorine-based resin such as polytetrafluoroethylene, and then transferred to the surface of the electrode by pressuring. In the case where the above-mentioned adhesive insulating composition is a hot-melt composition, the pressing may be performed while heating.

### 3. Circuit Article and Method for Manufacturing Same

The circuit article of the present invention is characterized in comprising the circuit board (I) and/or the circuit board (II) of the present invention. Specifically, the circuit article of the present invention may be [1] one or more of the circuit board (I) and/or one or more of the circuit board (II), or [2] one or more of the circuit board (I) and/or one or more of the circuit board (II), as well as other members (other circuit boards, electronic components, and the like). In the above embodiment (1), examples of particularly a composite circuit article include (A) a circuit article wherein surfaces of plural circuit boards (I) are joined, which is obtained by pressing the plural circuit boards (I) while using a separately prepared adhesive insulator (preferably the above-mentioned adhesive insulating composition) for integrating and leading to an electrical continuity, (B) a circuit article wherein a surface of the circuit board (I) and a surface of the circuit board (II) are joined, which is obtained using an adhesive insulating composition constituting the adhesive insulating area of the circuit board (II) for integrating the circuit board (I) and the circuit board (II), and leading to an electrical continuity, and the like. The embodiment in which plural circuit boards (II) are integrated to an electrical continuity will be described later.

The other circuit article of the present invention (hereinafter referred to as “circuit article (K1)”) is a circuit article comprising plural circuit boards of the present invention and wherein one circuit board and (one or more of) other circuit boards among the circuit boards are joined (at surfaces of the circuit boards) with an adhesive insulating composition that constitutes the adhesive insulating area of the one circuit board, and is characterized in that the one circuit board and the other circuit boards are in electrically connected due to contact between an electrode of the one circuit board and an electrode of the other circuit boards.

The method for manufacturing the circuit article (K1) of the present invention is characterized in selecting two circuit boards out of a plurality of the circuit boards (II), facing an electrode of the one circuit board to an electrode of the other circuit board; and attaching the two circuit boards to get electric contact between the two electrodes. The attaching method may be a pressing in which the circuit boards are pressed at ordinary temperature or an applying pressure (pressing) while heating at a temperature in the range from 30° C. to 80° C. (preferably from 30° C. to 60° C.). The pressure at pressing may be selected according to the material of the substrate that constitutes the circuit boards, the thickness of that material, and the components that constitute the adhesive insulating area. In the case where the adhesive insulating area is a hot-melt composition, the adhesive insulating composition constituting the adhesive insulating area will soften and move more quickly to a circumference of a surface where the electrodes are in contact. This case leads to a favorable contact between the electrodes and high adhesiveness between the circuit boards, being preferable.

The circuit article (K1) of the present invention will be described using FIG. 9. Specifically, in a circuit article 2 of the present invention, a circuit board 1a comprising a substrate 11a, an electrode 12a formed on a surface of this substrate 11a, and an adhesive insulating area 13a formed on a surface of this electrode 12a and a circuit board 1b comprising a substrate 11b, an electrode 12b formed on a surface of this substrate 11b, and an adhesive insulating area 13b formed on a surface of this electrode 12b are pressed or otherwise joined so that the electrodes of the circuit boards face one another. An electrical continuity in the circuit article 2 is obtained by making the adhesive insulating compositions that constitute the adhesive insulating areas of the circuit boards move to a circumference to join circuit boards while at the same time contacting the electrode 12a of the circuit board 11a and the electrode 12b of the circuit board 11b. The electrodes 12a and 12b are surrounded by the adhesive insulating compositions (joining parts 135a and 135b) constituting the adhesive insulating areas on the circuit boards.

Further, other circuit article of the present invention (hereinafter referred to as “circuit article (K2)”) is a circuit article comprising the circuit board (II) of the present invention and other circuit board (a circuit board not included in the present invention) provided with an electrode on the surface and wherein the above-mentioned circuit board (II) and the above-mentioned other circuit board are joined with an adhesive insulating composition that constitutes an adhesive insulating area of the circuit board (II), and is characterized in that circuits of both circuit boards are in electrically connected due to contact between an electrode of the above-mentioned circuit board (II) and an electrode of the above-mentioned other circuit board. The other circuit boards may one or more in number.

The method for manufacturing the other circuit article (K2) of the present invention is characterized in providing a circuit board which has an electrode on its surface (a circuit board not included in the present invention) and the circuit board (II), facing an electrode of the circuit board to an electrode of the other circuit board; and attaching the two circuit boards to get electric contact between the two electrodes. The attaching method is almost same as the case for the circuit article (K1).

The configuration of the other circuit board is not particularly limited. The constituent material and the shape of the substrate that constitutes the other circuit board, the constituent material of the electrode that is disposed on the substrate, the shape of the pattern, the surface roughness and the thickness of the electrode, and the like may be determined according to the purpose, application and the like.

The circuit article (K2) of the present invention will be described using FIG. 10. Specifically, in a circuit article 2′ of the present invention, a circuit board 1a comprising a substrate 11a, an electrode 12a formed on a surface of this substrate 11a, and an adhesive insulating area 13a formed on a surface of this electrode 12a and a circuit board 1c comprising a substrate 11c, and an electrode 12c formed on a surface of this substrate 11c (in the case of having a small area than the electrode 12a), are pressed or otherwise joined so that the electrodes of the circuit boards face one another. An electrical continuity in the circuit article 2′ is obtained by making polymers that constitute the adhesive insulating areas of the circuit boards and the like move to a circumference to join circuit boards while at the same time contacting the electrode 12a of the circuit board 11a and the electrode 12c of the circuit board 11c. The electrodes 12a and 12c are surrounded by the adhesive insulating compositions (joining parts 135a and 135b) constituting the adhesive insulating areas on the circuit boards.

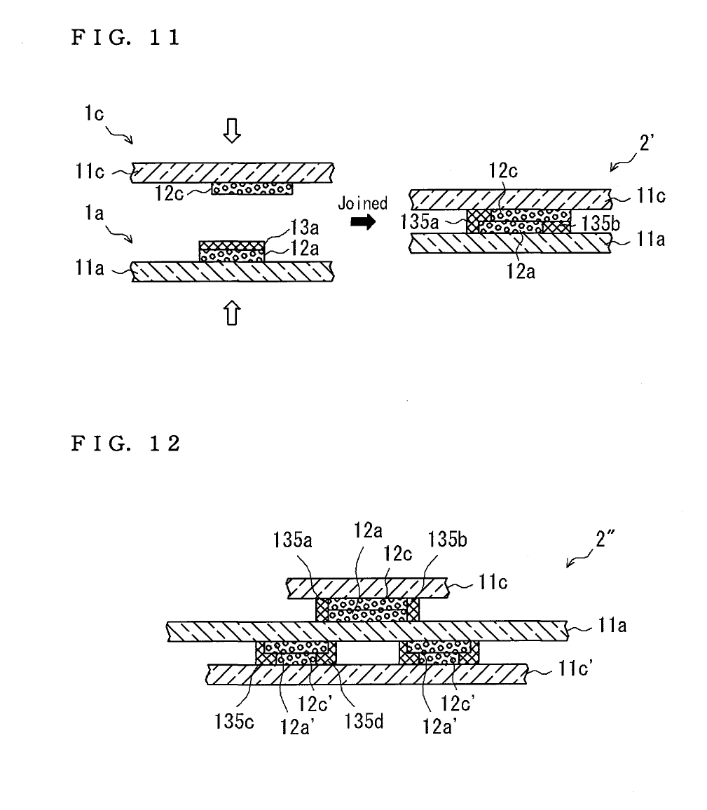

Further, the circuit article (K2) of the present invention may also be an embodiment as shown in FIG. 11. Specifically, in the circuit article 2′ shown in FIG. 11, a circuit board 1a comprising a substrate 11a, an electrode 12a formed on a surface of this substrate 11a, and an adhesive insulating area 13a formed on a surface of this electrode 12a and a circuit board 1c comprising a substrate 11c, and an electrode 12c formed on a surface of this substrate 11c (in the case of having a large area than the electrode 12a), are pressed or otherwise joined so that the electrodes of the circuit boards face one another. An electrical continuity in the circuit article 2 is obtained by making the adhesive insulating compositions that constitute the adhesive insulating areas of the circuit boards move to a circumference to join circuit boards while at the same time contacting the electrode 12a of the circuit board 11a and the electrode 12c of the circuit board 11c. The electrodes 12a and 12c are joined at the substrates of the circuit boards by the joining part 135a, but the substrate 11a and the electrode 12c are joined by the joining part 135b.

Moreover, a circuit article wherein other circuit boards are on both sides of a circuit board shown in FIG. 12 may also be used in the present invention. Specifically, a circuit article 2″ shown in FIG. 12 is a composite circuit board wherein a circuit board provided with other substrate 11c and an electrode 12c formed on this substrate 11c is joined to one side (the upper side in FIG. 12) of a circuit board provided with a substrate 11a, an electrode and an adhesive insulating area sequentially disposed on both side of the substrate 11a, and wherein a circuit board provided with other substrate 11c′ and two electrodes 12c′ formed on this substrate 11c′ is joined to the other side (the lower side in FIG. 12) of the above-mentioned circuit board. The electrodes 12c and 12c′ of the other two circuit boards on both sides are surrounded by the polymers and the like (the joining parts 135a and 135b, and, 135c and 135d, respectively) that constitute the adhesive insulating areas, as same as in FIGS. 9 and 10.

According to the circuit article of the present invention, plural circuit boards are closely bonded at their electrodes and the circuits are in electrically connected. The circuit article of the present invention is particularly ideal for thin-model products. In addition, since a circumference of the bonded electrodes is surrounded by the adhesive insulating composition in the circuit article of the present invention, moisture and heat resistance is excellent and a sharp downturn in electrically connected of the circuits never occurs.

### EXAMPLES

Hereinafter, examples will be given in order to explain the present invention in more detail. It shall be apparent that the present invention is not limited to these examples.

### 1. Production and Evaluation of the Conductive Paste

### 1-1. Raw Materials for the Conductive Paste

The raw material components used in the preparation of the conductive paste are as follows.

The silver powders shown in (A1) through (A5) below were used as the conductive material [A].

(A1): Scaly silver powder having mean particle diameter of 7.5 μm and specific surface area of 0.3 m²/g.
(A2): Scaly silver powder having mean particle diameter of 3.8 μm and specific surface area of 1.4 m²/g.
(A3): Granular silver powder having mean particle diameter of 2.0 μm and specific surface area of 1.1 m²/g.
(A4): Granular silver powder having mean particle diameter of 0.3 μm and specific surface area of 2.4 m²/g.
(A5): Granular silver powder having mean particle diameter of 0.2 μm and specific surface area of 2.2 m²/g.

Additionally, the polyester resins shown in (B1) and (B2) and the epoxy resin shown in (B3) below were used as the resin [B].

(B1): Saturated copolyester resin obtained by condensation polymerization using terephthalic acid, isophthalic acid, sebacic acid, ethylene glycol and neopentyl glycol as monomers.

The weight-average molecular weight is 20,000, glass transition temperature is 34° C., storage modulus is 210 MPa (25° C.), and the acid number is 3 KOH mg/g.

(B2): Saturated copolyester resin obtained by condensation polymerization using terephthalic acid, isophthalic acid, sebacic acid, ethylene glycol and neopentyl glycol as monomers.

The weight-average molecular weight is 20,000, glass transition temperature is 8° C., storage modulus is 57 MPa (25° C.), R and B softening point is 120° C., melt viscosity is 49,000 mPa·s (190° C.), and the acid number is 3 KOH mg/g.

(B3): Epoxy resin

The epoxy equivalent is 875 to 975 g/eq, softening point is 97° C., and molecular weight is 1,600. The storage modulus is 200 MPa (25° C.).

The glass transition temperature was measured in accordance with JIS K7121 using a differential scanning calorimeter “RDC220” manufactured by Seiko instruments Inc. The storage modulus was measured according to the parallel plate method at a measurement temperature range from 25° C. to 150° C., a rate of temperature increase of 3° C./min., and a frequency of 1 Hz, using a viscoelastmeter “RDS” manufactured by Rheometric Scientific Inc. Additionally, the R and B softening point was measured in accordance with JIS K6863. Butyl cellosolve acetate was used as a solvent.

### 1-2. Production and Evaluation of the Conductive Paste

### Example 1

40 parts by mass of the resin (B1) and 10 parts by mass of the resin (B3) mentioned above were dissolved in 150 parts by mass of butyl cellosolve acetate. After that 300 parts by mass of the conductive material (A1) was incorporated into this solution and performed mixing and dispersing using a three roll mill to prepare a uniform conductive paste (P1) (see Table 1). The viscosity measured at 25° C. using an E-type viscometer was 25,000 mPa·s.

This conductive paste was screen printed on a 100-μm thick polyester film, heated at 120° C. for 10 minutes and dried to form a film (50 mm long, 80 mm wide and 130 μm thick). The surface roughness (ten point height of roughness profile) and intrinsic volume resistivity of the film were measured. The results are shown in Table 1.

### (1) Ten Point Height of Roughness Profile

The average value of absolute values of the heights of the five highest peaks and the average value of absolute values of the heights of the five lowest troughs were determined in accordance with JIS B0601-2001 using a surface roughness measuring instrument “Surfcorder” manufactured by KOSAKA LABORATORY LTD.

### (2) Intrinsic Volume Resistivity

Measurement was performed according to a four-point probe array method using surface resistivity meter “Loresta GP” manufactured by DIA INSTRUMENTS CO., LTD.

### Examples 2 to 4 and Comparative Examples 1 to 3

Conductive pastes (P2) to (P7) were prepared in the same manner as Example 1, except that the conductive material [A], resin [B] and butyl cellosolve acetate used were mixed as described in Table 1 (see Table 1). The viscosity at 25° C. of the conductive pastes and the ten point height of roughness profile and volume resistivity of the films formed were measured in the same manner as Example 1. The results are shown in Table 1.

TABLE 1

| | | | | Example | | | | Comparative Example | | |
|---|---|---|---|---|---|---|---|---|---|---|
| | | | | 1 | 2 | 3 | 4 | 1 | 2 | 3 |
| Conductive paste | | | | (P1) | (P2) | (P3) | (P4) | (P5) | (P6) | (P7) |
| Formu- | Conductive | (A1) | | 300 | | 240 | 240 | 300 | | |
| lation | material | (A2) | | | 300 | 60 | | | | |
| (parts by | | (A3) | | | | | 60 | | | |
| mass) | | (A4) | | | | | | | 300 | |
| | | (A5) | | | | | | | | 300 |
| | Resin | (B1) | Storage | 40 | 40 | 40 | 40 | | 40 | 40 |
| | | | modulus | | | | | | | |
| | | | 210 MPa | | | | | | | |
| | | (B2) | Storage | | | | | 40 | | |
| | | | modulus | | | | | | | |
| | | | 57 MPa | | | | | | | |
| | | (B3) | Storage | 10 | 10 | 10 | 10 | 10 | 10 | 10 |
| | | | modulus | | | | | | | |
| | | | 200 MPa | | | | | | | |

| | | | | | | | | |
|---|---|---|---|---|---|---|---|---|
| | Butyl cellosolve acetate | 150 | 150 | 150 | 150 | 150 | 150 | 150 |
| Evalu- | Viscosity (mPa · s) | 25.0 × 10³ | 20.1 × 10³ | 24.5 × 10³ | 9.2 × 10³ | 15.0 × 10³ | 9.6 × 10³ | 9.0 × 10³ |
| ation | Ten-point height of roughness | 34.1 | 21.4 | 22.4 | 16.2 | 28.5 | 10.2 | 8.2 |
| | profile (μm) | | | | | | | |
| | Intrinsic volume resistivity | 1.4 × 10⁻⁴ | 1.9 × 10⁻⁴ | 1.6 × 10⁻⁴ | 9.7 × 10⁻⁵ | 8.4 × 10⁻³ | 6.7 × 10⁻³ | 1.5 × 10⁻⁴ |
| | (Ω · cm) | | | | | | | |

### 2. Production and evaluation of the circuit board and the circuit Article

2-1. Preparation of the adhesive insulating composition

An adhesive insulating compsoition (Q1) was prepared according To the guidelines below using a polymer (q1), a tackifier resin (q2), A liquid material (q3) and other components described below.

(1) Polymer (q1)

An SIS-based block copolymer “KRATON D-1107CP” manufactured by Shell Chemical Ltd. was used.

(2) Tackifier resin (q2)

A hydrogenated petroleum resin “ARKON P-115” manufactured by ARAKAWA CHEMCIAL INDUSTRIES LTD. was used.

(3) Liquid material (q3)

A process oil “DIANA PROCESS OIL PW-380” manufactured by Idemitsu Kosan Co., Ltd. was used.

(4) Anti-aging agent

Tetrakis [methylene 3-(3,5-di-tert-butyl-4-hydroxyphenyl) Propionate]methane “IRGANOX 1010” manufactured by Ciba Speciality Chemicals Inc. was used.

22.1 parts by mass of the polymer (q1), 55.1 parts by mass of the tackifier resin (q2) and 0.7 part by mass of the anti-aging agent were charged into a kneader which was heated to 170° C. and was under nitrogen gas flow, and melt-mixed for approximately 30 minutes. After that, 22.1 parts by mass of the liquid material (q3) was charged to melt-mix for approximately 60 minutes. Subsequently, defoaming was performed at 170° C. under a reduced pressure for approximately 30 minutes to prepare a hot-melt adhesive insulating composition (Q1). The storage modulus (25° C.), melt viscosity (190° C.), and R and B softening point of the adhesive insulating composition (Q1) are shown in Table 2.

TABLE 2

| | | Adhesive insulating |
|---|---|---|
| | | composition (Q1) |
| Formulation | Polymer (q1) | 22.1 |
| (parts by | Tackifier resin (q2) | 55.1 |
| mass) | Liquid material (q3) | 22.1 |
| | Anti-aging agent | 0.7 |
| | Total | 100 |
| Ratio | Mass ratio (q1)/(q2) | 28.6/71.4 |
| | Mass ratio [(q1) + (q2)]/(q3) | 100/28.6 |
| Property | Storage modulus (MPa) | 0.035 |
| | Melt viscosity (mPa · s) | 2,200 |
| | R & B softening point (° C.) | 90 |

2-2. Production and evaluation of the circuit board and the circuit article

### Example 5

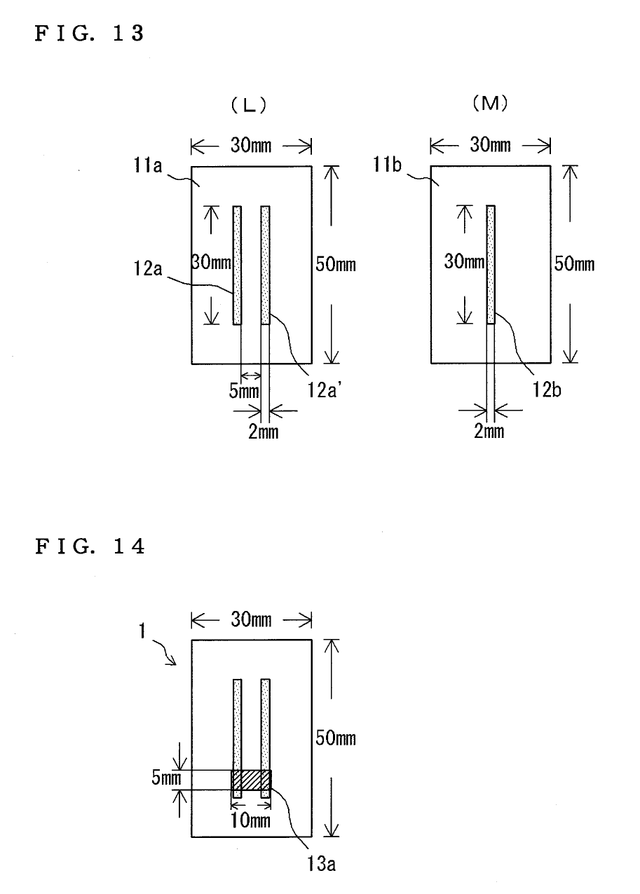

The conductive paste (P1) was used to screen print according to the patterns shown in (L) and (M) of FIG. 13 onto two 100-μm thick polyester films (substrates 11a and 11b). After that, heating was performed at 120° C. for 10 minutes to dry. A film was formed (the size of one pattern was 30 mm long, 2 mm wide and 130 μm thick), and a layered substrate (L) and a circuit board (M) were obtained. The two patterns of the layered substrate (L) in FIG. 13 were made into electrodes 12a and 12a′, and the single pattern of the circuit board (M) in FIG. 13 was made into an electrode 12b.

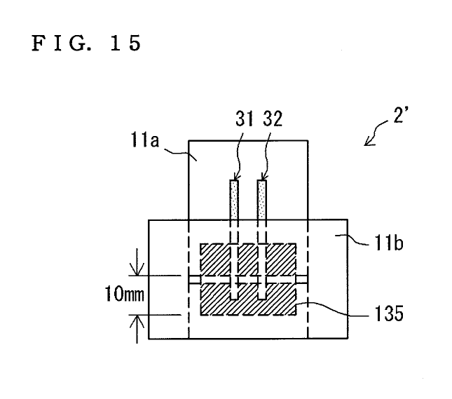

Subsequently, the adhesive insulating composition (Q1) was coated on the layered substrate (L) shown in FIG. 13 so as to be perpendicular to the two electrodes 12a and 12a′ of the layered substrate (L). An adhesive insulating area 13a having 5 mm long, 10 mm wide and 50 μm thick was formed and a circuit board 1 was obtained (see FIG. 14). Then the circuit board 1 (see FIG. 14) and the circuit board (M) shown in FIG. 13 were overlaid as shown in FIG. 15 to press at a pressure of 0.1 MPa and at a temperature of 25° C. for 1 second, and a circuit article 2′ was obtained.

A tester was brought into contact with tips 31 and 32 (resistance measuring position) of the electrodes shown in FIG. 15, and the resistance of the resulting circuit article 2′ was measured. In addition, this circuit article was let to stand in an environment having a temperature of 65° C. and a humidity of 93% RH for 168 hours (moisture and heat resistance test), and the resistance was measured in the same manner. The results are shown in Table 3.

### Examples 6 to 8 and Comparative Examples 4 to 6

Circuit boards and circuit articles were produced and evaluated in the same manner as Example 5, except that the conductive paste and the adhesive insulating composition were used in the combinations described in Tables 3 and 4. The results are shown in Table 3.

TABLE 3

| | | | Example | | | | Comparative Example | | |
|---|---|---|---|---|---|---|---|---|---|
| | | | 5 | 6 | 7 | 8 | 4 | 5 | 6 |
| Configuration | Electrode | Conductive paste | (P1) | (P2) | (P3) | (P4) | (P5) | (P6) | (P7) |
| of circuit | | Thickness (μm) | 130 | 125 | 150 | 110 | 110 | 110 | 80 |
| board | Adhesive | Adhesive insulating | (Q1) | (Q1) | (Q1) | (Q1) | (Q1) | (Q1) | (Q1) |
| | insulating | composition | | | | | | | |
| | part | Thickness (μm) | 50 | 50 | 50 | 50 | 50 | 50 | 50 |
| Evaluation of | Resistance | After pressing | 2.1 | 2.8 | 2.1 | 1.1 | 16*¹ | 50 | ≧300M |
| circuit | (Ω) | After moisture and | 2.4 | 2.6 | 2.5 | 1.8 | ≧300M*² | 153 | ≧300M |
| article | | heat resistance test | | | | | | | |

*¹Resistance became higher as time goes by.
*²Detection limit was exceeded.

According to Table 3, it is found that Examples 5 to 8 all had excellent electrical conduction and led stable performances even after the moisture and heat resistance test. On the other hand, it is found that Comparative Examples 4 to 6 did not lead sufficient performances.

### INDUSTRIAL APPLICABILITY

The present invention is suitable for a highly productive circuit and a production available for a lighter, more compact and low-cost design electronic component such as RFID tags (including non-contact ID tags and non-contact ID cards).

What is claimed is:

1. A conductive paste characterized in comprising a conductive material that is scaly, has a mean particle diameter of 1 μm or more and 10 μm or less, and is at least one material selected from the group consisting of Ag, an Ag alloy, an Ag-coated material, and an Ag alloy-coated material, and a resin that has a storage modulus at 25° C. of 100 MPa or more.

2. The conductive paste according to claim 1,
wherein said resin is a polyester resin.

3. A circuit board characterized in comprising a substrate and an electrode which is formed at least on one surface of said substrate using said conductive paste according to claim 1.

4. The circuit board according to claim 3,
wherein said circuit board is used for forming an adhesive insulating area, which comprises a composition having a storage modulus that is smaller than the storage modulus at 25° C. of said resin contained in said conductive paste, on a surface of said electrode.

5. The circuit board according to claim 3,
wherein a ten point height of roughness profile of a surface of said electrode is 15 μm or more.

6. The circuit board according to claim 3,
wherein said circuit board further comprises an adhesive insulating area on a surface of said electrode, and
wherein a storage modulus at 25° C. of a composition that constitutes said adhesive insulating area is smaller than a storage modulus at 25° C. of said resin that is contained in said conductive paste.

7. The circuit board according to claim 6,
wherein said adhesive insulating area comprises at least one polymer selected from the group consisting of a styrene-isoprene-styrene block copolymer, a styrene-butadiene-styrene block copolymer and hydrogenated polymers of these polymers, a tackifier resin, and an oil and/or a liquid hydrocarbon-based plasticizer.

8. The circuit board according to claim 7,
wherein content of said polymer is in the range from 10 to 60 parts by mass based on 100 parts by mass of total of said polymer and said tackifier resin.

9. The circuit board according to claim 7,
wherein total content of said oil and/or said liquid hydrocarbon-based plasticizer is in the range from 5 to 30 parts by mass based on 100 parts by mass of total of said polymer and said tackifier resin.

10. A circuit article characterized in comprising said circuit board according to claim 3.

11. A circuit article which comprises a plurality of said circuit boards according to claim 6, and wherein one circuit board and other circuit boards among said circuit boards are joined with an adhesive insulating composition that constitutes the adhesive insulating area of said one circuit board, characterized in that said one circuit board and said other circuit boards are in electrically connected due to contact between an electrode of said one circuit board and an electrode of said other circuit boards.

12. A circuit article which comprises said circuit board according to claim 6 and another circuit board provided with an electrode on its surface, wherein said circuit board and said another circuit board are joined with an adhesive insulating composition that constitutes an adhesive insulating area of said circuit board, characterized in that circuits of both circuit boards are in electrically connected due to contact between an electrode of said circuit board and an electrode of said another circuit board.

13. A method for manufacturing a circuit article, characterized in comprising:
selecting two circuit boards out of a plurality of said circuit boards according to claim 6,
facing an electrode of the one circuit board to an electrode of the other circuit board; and
attaching the two circuit boards by using adhesive insulating compositions that constitute adhesive insulating area on the each circuit board, while getting electric contact between the two electrodes.

14. The method for manufacturing a circuit article according to claim 13,
wherein said attaching process involves applying pressure while heating.

15. A method for manufacturing a circuit article, characterized in comprising:
providing a circuit board which has an electrode on its surface and said circuit board according to claim 6,
facing an electrode of the circuit board to an electrode of the other circuit board; and
attaching the two circuit boards by using adhesive insulating compositions that constitute adhesive insulating area on the each circuit board, while getting electric contact between the two electrodes.

16. The method for manufacturing a circuit article according to claim 15,
wherein said attaching process involves applying pressure while heating.
